(19) United States
(12) Patent Application Publication
(10) Pub. No.: US 2021/0328197 A1
(43) Pub. Date: Oct. 21, 2021

(54) OLED DISPLAY PANEL AND METHOD FOR FABRICATING THE SAME

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Qiankun XU, Shenzhen, Guangdong (CN); Xiaoxing ZHANG, Shenzhen, Guangdong (CN)

(21) Appl. No.: 16/622,934

(22) PCT Filed: Nov. 18, 2019
(86) PCT No.: PCT/CN2019/119084

§ 371 Date: Dec. 16, 2019

(30) Foreign Application Priority Data
Oct. 31, 2019 (CN) 201911050510.9

(51) Int. Cl. H01L 51/52; H01L 51/56

(52) U.S. Cl. CPC H01L 51/5284; H01L 51/56

(57) ABSTRACT

An OLED display panel and a method for fabricating the same are provided. The OLED display panel includes a substrate; a black matrix attached to a side surface of the substrate; a first color resist sheet attached to a surface of the black matrix away from the substrate; a second color resist sheet attached to a surface of the first color resist sheet away from the substrate; a third color resist sheet attached to a surface of the second color resist sheet away from the substrate; and a first color resist layer, a second color resist layer, and a third color resist layer respectively attached to the side surface of the substrate and between two of the black matrices adjacent to each other. A total lamination thickness of the black matrix and the first, second, and third color resist sheets is greater than a thickness of any color resist layer.

### FIELD OF DISCLOSURE

The present disclosure relates to the field of display technologies, and particularly relates to an OLED display panel and a method for fabricating the same.

### BACKGROUND OF DISCLOSURE

An organic light emitting diode (OLED) display device has many advantages, such as self-illumination, low driving voltage, high luminous efficiency, short response time, high definition and contrast, nearly 180° angle of view, wide operating temperature range, flexible display, and large area full-color display, etc., which is considered as the new application technology of next generation flat panel display in the industry

Compared with a bottom emission OLED display device, a top emission OLED display device has advantages of a large aperture ratio and a low power consumption, and is widely applied to a small-sized screen display, such as a mobile phone. For the display screen of the top emission and color filter (CF) substrate, it is sometimes necessary to prepare protruding structures, such as elevated platforms or post spacers (PSs) on the CF cover plate to facilitate the cell package by aligning the CF cover plate with the substrate. Furthermore, a thickness of the CF package cell is increased in OLED products, and an auxiliary cathode can be prepared on the high platform.

### SUMMARY OF DISCLOSURE

### Technical Problems

At present, a common preparation process of protrusions is to perform a yellow light process after a CF cover plate is completed. As shown in FIG. 1, a black matrix 101, color resist units 102 with RGB colors, and an over coat (OC) 103 are sequentially prepared on a color filter substrate 100, and then post spacers (PSs) 104 are prepared by a yellow light process. The overall preparation process is too complicated.

### Technical Solutions

The present disclosure provides an OLED display panel and a method for fabricating the same, which can prepare protrusion structures by the superposition of color resists, thereby reducing additional processes of preparing the PSs, the overall process time, and the manufacturing cost.

The present disclosure provides an OLED display panel comprising a substrate; a black matrix attached to a side surface of the substrate; a first color resist sheet attached to a surface of the black matrix away from the side surface of the substrate; a second color resist sheet attached to a surface of the first color resist sheet away from the side surface of the substrate; a third color resist sheet attached to a surface of the second color resist sheet away from the side surface of the substrate; and a first color resist layer, a second color resist layer, and a third color resist layer respectively attached to the side surface of the substrate, and disposed between two of the black matrices adjacent to each other. A total lamination thickness of the black matrix, the first color resist sheet, the second color resist sheet, and the third color resist sheet is greater than a thickness of any color one of resist layers.

Further, the first color resist sheet is connected to the first color resist layer; and/or the second color resist sheet is connected to the second color resist layer; and/or the third color resist sheet is connected to the third color resist layer.

Further, the second color resist sheet completely covers or partially covers the first color resist sheet; and the third color resist sheet completely covers or partially covers the second color resist sheet.

Further, colors of the first color resist sheet or the first color resist layer, the second color resist sheet or the second color resist layer, and the third color resist sheet or the third color resist layer are respectively one of red, green, and blue; the colors of the first color resist sheet or the first color resist layer, the second color resist sheet or the second color resist layer, and the third color resist sheet or the third color resist layer are different from each other.

Further, a plurality of the black matrices are uniformly distributed on the side surface of the substrate.

Further, the OLED display panel further comprises an over coat. The over coat attached to the first color resist, the second color resist, the third color resist, the first color resist layer, the second color resist layer, and the third color resist layer.

Further, a total lamination thickness of the black matrix, the first color resist sheet, the second color resist sheet, the third color resist sheet, and the over coat is greater than a total lamination thickness of any one of color resist layers, and the over coat.

The present disclosure also provides a method for fabricating the same comprising the steps as follows: a black matrix preparation step of preparing a black matrix on a substrate uniformly; a first color resist preparation step of preparing a first color resist sheet on an upper surface of the black matrix, and simultaneously preparing a first color resist layer on an upper surface of the substrate and between two of the black matrices adjacent to each other; a second color resist preparation step of preparing a second color resist sheet on an upper surface of the first color resist sheet on the black matrix, and simultaneously preparing a second color resist layer on the upper surface of the substrate and between two of the black matrices adjacent to each other; and a third color resist preparation step of preparing a third color resist sheet on an upper surface of the second color resist sheet on the black matrix, and simultaneously preparing a third color resist layer on the upper surface of the substrate and between two of the black matrices adjacent to each other; wherein a total thickness of the black matrix, the first color resist sheet, the second color resist sheet, and the third color resist sheet after the above-mentioned preparation steps is greater than a thickness of any one of color resist layers.

Further, the method further comprises an over coat preparation step of preparing an over coat on upper layers of the first color resist, the second color resist, the third color resist, the first color resist layer, the second color resist layer, and the third color resist layer.

Further, a total lamination thickness of the black matrix, the first color resist sheet, the second color resist sheet, and the third color resist sheet after the over coat preparation step is greater than a total lamination thickness of any one of color resist layers, and the over coat.

### BENEFICIAL EFFECTS

An advantage of the present disclosure is to provide an OLED display panel and a method for fabricating the same, wherein the protrusion structures are formed on the substrate by the superposition of the color resists, which can omit the process of preparing the PSs in the conventional process, thereby reducing the overall process time and the manufacturing cost. Moreover, since the color resists have the mutual shading effect therebetween, the optical light leakage can be prevented.

### DESCRIPTION OF DRAWINGS

FIG. 1 is a schematic view showing a structure of post spacers (PSs) prepared by a yellow light process in the prior art.

FIG. 2 is a schematic view showing a structure after a black matrix preparation step is completed according to an embodiment of the present disclosure.

FIG. 3 is a schematic view showing a structure after a first color resist preparation step is completed according to an embodiment of the present disclosure.

FIG. 4 is a schematic view showing a structure after a second color resist preparation step is completed according to an embodiment of the present disclosure.

FIG. 5 is a schematic view showing a structure after a third color resist preparation step is completed according to an embodiment of the present disclosure.

FIG. 6 is a schematic view showing a structure after all the preparation steps are completed according to an embodiment of the present disclosure.

FIG. 7 is a schematic view showing a structure after all the preparation steps are completed according to another embodiment of the present disclosure.

FIG. 8 is a flowchart of preparation steps according to an embodiment of the present disclosure.

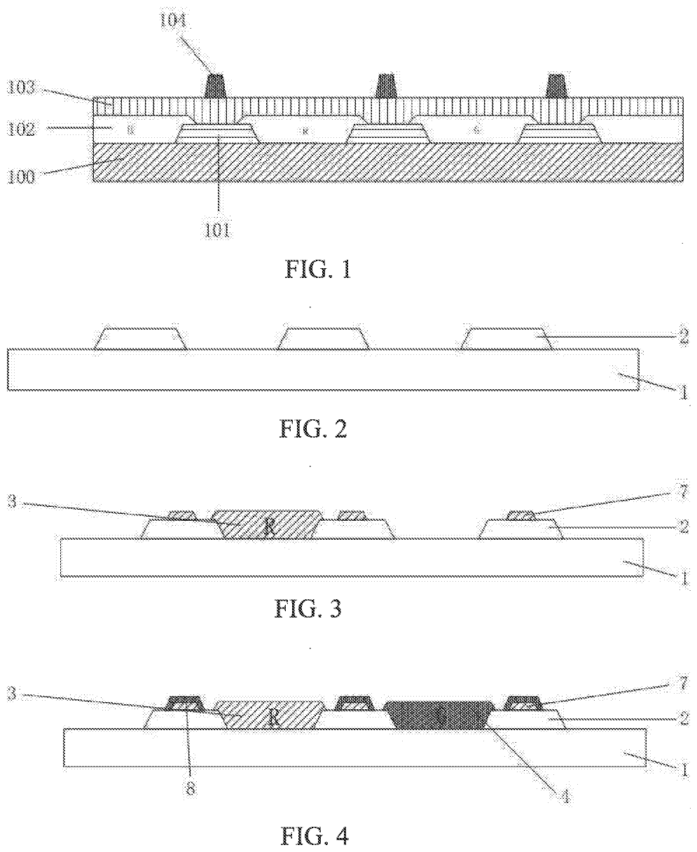

### DETAILED DESCRIPTION OF PREFERRED EMBODIMENTS

The present disclosure will be further described below with reference to the accompanying drawings and embodiments. It should be understood that the specific embodiments of the present disclosure described herein are merely illustrative of the present disclosure and are not intended to limit the present disclosure. It should also be noted that, for ease of description, only some, but not all, of the structures related to the present disclosure are shown in the drawings.

Directional terms mentioned in the present disclosure, such as “top”, “bottom”, “front”, “back”, “left”, “right”, “inside”, “outside”, “side” etc., are only used with reference to the orientation of the accompanying drawings. Therefore, the used directional terms are intended to illustrate, but not to limit, the scope of the present disclosure.

When a component is described as “being on” another component, the component can be placed directly on another component; or there may be an intermediate component, wherein the component is placed on the intermediate component, and the intermediate component is placed on another component. When a component is described as “mounted to” or “connected to” another component, both can be understood as directly “mounted” or “connected”, or a component is “mounted to” or “connected to” another component via an intermediate component.

As shown in FIG. 6, in an embodiment of the present disclosure, a display panel comprises a substrate 1, a plurality of black matrices 2 uniformly distributed on the substrate 1, a first color resist sheet 7 attached to each the black matrix 2, a second color resist sheet 8 attached to each the first color resist sheet 7, a third color resist sheet 9 attached to each the second color resist sheet 8, and a first color resist layer 3, a second color resist layer 4, and a third color resist layer 5 disposed between two of the black matrices 2 adjacent to each other and attached on the substrate 1.

In an embodiment of the present disclosure, the first color resist sheet 7 and the first color resist layer 3 are red color resists, the second color resist sheet 8 and the second color resist layer 4 are green color resists, and the third color resist sheet 9 and the third color resist layer 5 are blue color resists, but the disclosure is not limited thereto. The colors of the three groups of the color resist sheets and the color resist layers may be any one of red, green, and blue, as long as the colors thereof are different from each other.

As shown in FIG. 6, the second color resist sheet 8 completely covers the first color resist sheet 7, and the third color resist sheet 9 completely covers the second color resist sheet 8. Since the color resists with different colors have a mutual shading effect therebetween, for example, the light passing through the red color resist will not pass through the green color resist or the blue color resist, the optical light leakage can be prevented.

A total lamination thickness of the black matrix 2, the first color resist sheet 7, the second color resist sheet 8, and the third color resist sheet 9 is greater than a thickness of any one of the first color resist layer 3, the second color resist layer 4, and third color resist layer 5. The color resists with different colors are superposed on each other to form protrusion structures, which can increase a thickness of the package cell, and overlap the substrate, thereby reducing the post spacer (PS) preparation process in the conventional process, the overall process time, and the manufacturing cost.

An over coat 6 is further attached on the first color resist sheet 7, the second color resist sheet 8, the third color resist sheet 9, the first color resist layer 3, the second color resist layer 4, and third color resist layer 5. A total lamination thickness of the black matrix 2, the first color resist sheet 7, the second color resist sheet 8, the third color resist sheet 9, and the over coat 6 is greater than a total lamination thickness of any one of the first color resist layer 3, the second color resist layer 4, and third color resist layer 5, and the over coat 6.

In another embodiment of the present disclosure, as shown in FIG. 7, a portion of the first color resist sheet 7 is connected to the first color resist layer 3, a portion of the second color resist sheet 8 is connected to the second color resist layer 4, and a portion of the third color resist sheet 9 is connected to the third color resist layer 5, so as to form a large color resist block shape. Also, the first color resist sheet 7, the second color resist sheet 8, and the third color resist sheet 9 are in a semi-covered state therebetween. Although the structure is slightly different from the previous embodiment, protrusion structures can also be formed by the superposition of different color resists therebetween, which can increase the thickness of the package cell, and overlap the substrate, thereby preventing the optical light leakage, and reducing the overall process time and the manufacturing cost.

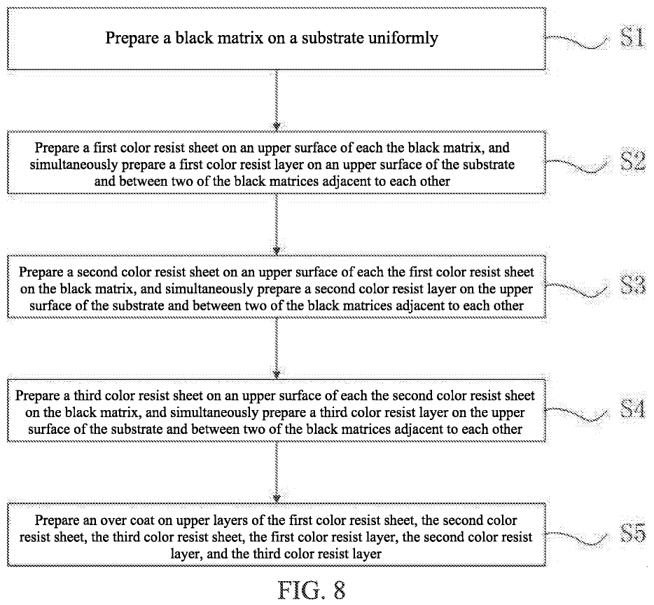

In an embodiment of the present disclosure, a method for fabricating a display panel is also provided. As shown in FIG. 8, the method comprises the steps as follows.

(S1) A black matrix preparation step is to prepare the black matrix 2 on the substrate 1 uniformly. The structure after the preparation is shown in FIG. 2.

(S3) A first color resist preparation step is to prepare the first color resist sheet 7 on an upper surface of each the black matrix 2, and simultaneously prepare the first color resist layer 3 on an upper surface of the substrate 1 and between two of the black matrices 2 adjacent to each other. The structure after preparation is shown in FIG. 3.

(S3) A second color resist preparation step is to prepare the second color resist sheet 8 on an upper surface of each the first color resist sheet 7 on the black matrix 2, and simultaneously prepare the second color resist layer 8 on the upper surface of the substrate 1 and between two of the black matrices 2 adjacent to each other. The structure after preparation is shown in FIG. 4.

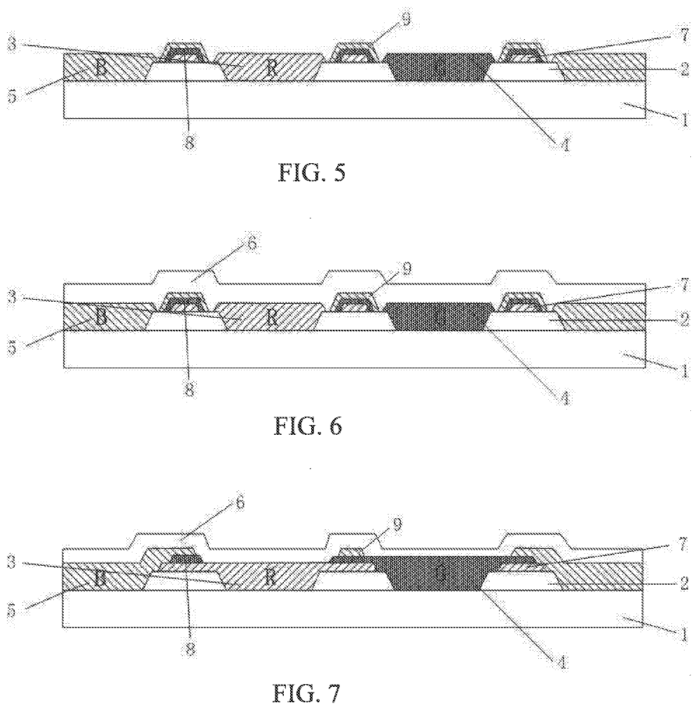

(S4) A third color resist preparation step is to prepare the third color resist sheet 9 on an upper surface of each the second color resist sheet on the black matrix 2, and simultaneously prepare the third color resist layer 5 on the upper surface of the substrate 1 and between two of the black matrices 2 adjacent to each other. The structure after preparation is shown in FIG. 5.

(S5) An over coat preparation step is to prepare the over coat 6 on upper layers of the first color resist sheet 7, the second color resist sheet 8, the third color resist sheet 9, the first color resist layer 3, the second color resist layer 4, and the third color resist layer 5. The structure after preparation is shown in FIG. 6.

As described above, after the preparation is completed, a total lamination thickness of the black matrix 2, the first color resist sheet 7, the second color resist sheet 8, the third color resist sheet 9, and the over coat 6 is greater than a total lamination thickness of any one of the first color resist layer 3, the second color resist layer 4, and third color resist layer 5, and the over coat 6. Compared with the conventional process, the process of preparing the PSs by the yellow light process is omitted, thereby reducing the overall process time and the manufacturing cost.

In summary, the present disclosure provides an OLED display panel and a method for fabricating the same. The protrusion structures are formed on the substrate by the superposition of the color resists, which can omit the process of preparing the PSs in the conventional process, thereby reducing the overall process time and the manufacturing cost. Moreover, since the color resists have the mutual shading effect therebetween, the optical light leakage can be prevented.

The above are only the preferred embodiments of the present disclosure, and are not intended to limit the present disclosure. Any modifications, equivalent replacement, and improvements made within the spirit and scope of the present disclosure shall be included in the scope of protection of the present disclosure.

1. An OLED display panel, comprising:
a substrate;
a black matrix attached to a side surface of the substrate;
a first color resist sheet attached to a surface of the black matrix away from the side surface of the substrate;
a second color resist sheet attached to a surface of the first color resist sheet away from the side surface of the substrate;
a third color resist sheet attached to a surface of the second color resist sheet away from the side surface of the substrate; and
a first color resist layer, a second color resist layer, and a third color resist layer respectively attached to the side surface of the substrate, and disposed between two of the black matrices adjacent to each other;
wherein a total lamination thickness of the black matrix, the first color resist sheet, the second color resist sheet, and the third color resist sheet is greater than a thickness of any one of the first, second, and third color resist layers.

2. The OLED display panel according to claim 1, wherein the first color resist sheet is connected to the first color resist layer, the second color resist sheet is connected to the second color resist layer, or the third color resist sheet is connected to the third color resist layer.

3. The OLED display panel according to claim 1, wherein the second color resist sheet completely covers or partially covers the first color resist sheet; and the third color resist sheet completely covers or partially covers the second color resist sheet.

4. The OLED display panel according to claim 1, wherein colors of the first color resist sheet or the first color resist layer, the second color resist sheet or the second color resist layer, and the third color resist sheet or the third color resist layer are respectively one of red, green, and blue; the colors of the first color resist sheet or the first color resist layer, the second color resist sheet or the second color resist layer, and the third color resist sheet or the third color resist layer are different from each other.

5. The OLED display panel according to claim 1, wherein a plurality of the black matrices are uniformly distributed on the side surface of the substrate.

6. The OLED display panel according to claim 1, further comprising:
an over coat attached to the first color resist sheet, the second color resist sheet, the third color resist sheet, the first color resist layer, the second color resist layer, and the third color resist layer.

7. The OLED display panel according to claim 6,
wherein a total lamination thickness of the black matrix, the first color resist sheet, the second color resist sheet, the third color resist sheet, and the over coat is greater than a total lamination thickness of any one of the first, second, and third color resist layers, and the over coat

8. A method for fabricating an OLED display panel, comprising:
a black matrix preparation step of preparing a black matrix on a substrate uniformly;
a first color resist preparation step of preparing a first color resist sheet on an upper surface of the black matrix, and simultaneously preparing a first color resist layer on an upper surface of the substrate and between two of the black matrices adjacent to each other;
a second color resist preparation step of preparing a second color resist sheet on an upper surface of the first color resist sheet on the black matrix, and simultaneously preparing a second color resist layer on the upper surface of the substrate and between two of the black matrices adjacent to each other; and
a third color resist preparation step of preparing a third color resist sheet on an upper surface of the second color resist sheet on the black matrix, and simultaneously preparing a third color resist layer on the upper surface of the substrate and between two of the black matrices adjacent to each other;
wherein a total thickness of the black matrix, the first color resist sheet, the second color resist sheet, and the third color resist sheet after the black matrix, first color resist, second color resist, and third color resist preparation steps is greater than a thickness of any one of the first, second, and third color resist layers.

9. The method for fabricating the OLED display panel according to claim 8, further comprising:
an over coat preparation step of preparing an over coat on upper layers of the first color resist sheet, the second color resist sheet, the third color resist sheet, the first color resist layer, the second color resist layer, and the third color resist layer.

10. The method for fabricating the OLED display panel according to claim 8, wherein a total lamination thickness of the black matrix, the first color resist sheet, the second color resist sheet, and the third color resist sheet after the over coat preparation step is greater than a total lamination thickness of any one of the first, second, and third color resist layers, and the over coat.
